(19) United States
(12) Patent Application Publication
(10) Pub. No.: US 2026/0089871 A1
(43) Pub. Date: Mar. 26, 2026

(54) NON-UNIFORM HEATSINK FIN GEOMETRY FOR INCREASED THERMAL PERFORMANCE

(71) Applicant: NVIDIA CORPORATION, Santa Clara, CA (US)

(72) Inventors: Malcolm GUTENBURG, San Francisco, CA (US); Yunseok KIM, Pleasanton, CA (US); Boris LANDWEHR, Los Gatos, CA (US); Jaekyu JUNG, Los Gatos, CA (US); Jungho NA, Milpitas, CA (US); Siarhei MURAUYOU, Los Gatos, CA (US)

(21) Appl. No.: 18/892,266

(22) Filed: Sep. 20, 2024

(51) Int. Cl. H05K 7/20; G06F 1/20

(52) U.S. Cl. CPC H05K 7/20154; G06F 1/20

(57) ABSTRACT

According to various embodiments, a heatsink includes: a plurality of cooling fins, wherein a first cooling fin included in the plurality of cooling fins has a first portion with a first height and has a second portion with a second height that is less than the first height, and wherein the first height and the second height are defined in a direction that is parallel with a direction of cooling air flowing across the plurality of cooling fins.

### BACKGROUND

### Field of the Various Embodiments

The various embodiments relate generally to computer systems and thermal solution technology and, more specifically, to non-uniform heatsink fin geometry for increased thermal performance.

### Description of the Related Art

In modern computing devices, central processing units (CPUs), graphics processing units (GPUs), and other integrated circuits (ICs) generate significant quantities of heat during operation. This heat needs to be removed from the computing device in order for the integrated circuits and the computing device, as a whole, to operate effectively. For example, a single high-power chip, such as a CPU or GPU, can generate hundreds of watts of heat during operation. If this heat is not removed from the computing device, then the temperature of the chip can increase to a point where the chip can be permanently damaged. Therefore, to prevent thermal damage during operation, many computing devices incorporate various cooling systems that remove heat generated by the chip and other electronic components within the computing devices. In addition to conventional cooling systems, many computing devices also implement clock-speed throttling when the operating temperature of a processor exceeds a certain threshold. Thus, in these computing devices, the processing speed of the high-power chip is constrained by how effectively heat is removed from the chip, which can decrease the overall computational effectiveness of the computing devices.

For many card-based processing subsystems, such as a graphics card with a high-power chip or GPU, removal of heat generated by the chip is facilitated by the use of a fan-based cooling system. Typically, with these types of cooling systems, one or more axial fans direct air across the cooling fins of a heatsink that removes heat from the electronic components included in the card-based processing subsystem, thereby greatly increasing the cooling capacity of the heatsink.

One drawback of fan-based cooling systems is that the air directed across the cooling fins of a heatsink generally has a highly nonuniform velocity distribution, ranging from a high discharge velocity at the perimeter of the fan to low or zero discharge velocity at the hub of the fan. The nonuniform velocity distribution of the air discharged by the axial fans of fan-based cooling system is caused by each fan blade generating more pressure at the blade tip than at the blade base. Typically, an axial fan blade generates pressure as a function of the linear speed of the blade at each point along the blade. Because the linear speed of a point along the blade is directly proportional to the radial location of the point, higher pressure is generated by a fan blade farther from the hub of the fan, and lower pressure is generated by the fan blade closer to the hub of the fan. As a result, an axial fan generally discharges higher velocity air near the blade tips and lower velocity air near the hub of the fan.

In light of the above, significant portions of the cooling fins of a heatsink can receive little or no cooling air while other portions of the cooling fins receive high-velocity cooling air. The portions of the cooling fins that receive little or no cooling air provide limited heat transfer from the heatsink. This underutilization of the cooling fins reduces the cooling efficiency of the heatsink and the fan-based cooling system as a whole, and typically results in less heat being removed from the heatsink. Because a total air flow rate for fan-based cooling systems is usually limited to avoid generating unwanted levels of fan noise, the flow rate of the fans included in these types of fan-based cooling systems cannot simply be increased to compensate for the loss in cooling efficiency caused by such underutilization of the cooling fins.

In an attempt to equalize the velocity distribution across the diameter of an axial fan, the blades of an axial fan are sometimes configured with a variable angle of attack that increases from a minimum angle at the blade tip to a maximum value at the blade base. However, the compact axial fans typically employed in many card-based processing subsystems operate at relatively high rotational speeds, for example on the order of 3,000 rotations per minute or more. At such rotational speeds, incorporating a variable angle of attack into the blade geometry generally does not eliminate or even sufficiently reduce the nonuniform velocity distribution of the air discharged air by these fans.

As the foregoing illustrates, what is needed in the art are more effective techniques for removing heat from card-based processing subsystems.

### SUMMARY

According to various embodiments, a heatsink includes: a plurality of cooling fins, wherein a first cooling fin included in the plurality of cooling fins has a first portion with a first height and has a second portion with a second height that is less than the first height, and wherein the first height and the second height are defined in a direction that is parallel with a direction of cooling air flowing across the plurality of cooling fins.

At least one technical advantage of the disclosed design relative to the prior art is that the disclosed design can increase the thermal performance of a fan-based cooling system by more evenly distributing the flow of cooling air across the cooling fins of a heatsink. In particular, the disclosed design changes the fluidic impedance of the cooling fins of the heatsink locally, which reduces the pressure drop caused by the cooling fins in a region of the heatsink facing the fan hub relative to the pressure drop caused by the cooling fins in a region of the heatsink facing the fan perimeter. Consequently, the velocity distribution of air flowing through the cooling fins of a heatsink in accordance with the disclosed design is more equalized or more uniform relative to the velocity distribution of air flowing though the cooling fins of a conventional heatsink. As a result, thermal performance of the heatsink, and the fan-based cooling system as a whole, is increased. These technical advantages provide one or more technological advancements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is a conceptual illustration of a computer system configured to implement one or more aspects of the various embodiments.

FIG. 2 is another illustration of the computer system of FIG. 1, according to various embodiments.

FIG. 3 is a more detailed illustration of the card-based processing subsystem of FIG. 2, according to various embodiments.

FIG. 4 is a closer perspective view of one portion of the card-based processing subsystem of FIG. 3, according to various embodiments.

FIG. 5 is a cross-sectional view of the card-based processing subsystem of FIG. 3, according to various embodiments.

FIG. 6 illustrates a discharge velocity profile of a cooling fan included in the card-based processing subsystem of FIG. 3, according to various embodiments.

FIG. 7 illustrates a velocity profile of cooling air entering a fin array of a heatsink, according to various embodiments.

FIG. 8 illustrates a cooling fin of a heatsink having stepwise changes in fin height, according to various embodiments.

FIG. 9 illustrates a cooling fin of a heatsink having a curved leading edge, according to various embodiments.

FIG. 10 illustrates a cooling fin of a heatsink having a both a curved leading edge and a curved trailing edge, according to various embodiments.

For clarity, identical reference numbers have been used, where applicable, to designate identical elements that are common between figures. It is contemplated that features of one embodiment may be incorporated in other embodiments without further recitation.

### DETAILED DESCRIPTION

In the following description, numerous specific details are set forth to provide a more thorough understanding of the various embodiments. However, it will be apparent to one of skilled in the art that the inventive concepts may be practiced without one or more of these specific details.

### Introduction

According to various embodiments, a fin array for a heatsink in a fan-based cooling system is configured to increase the thermal performance of the heatsink by more evenly distributing the flow of cooling air that is directed across the cooling fins of the heatsink by a fan. In the embodiments, the fin array includes a first region that corresponds to a high-velocity discharge region of the fan (such as a perimeter region of the fan) and a second region that corresponds to a low-velocity discharge region of the fan (such as a hub region of the fan). In such embodiments, the first region of the fin array faces and receives cooling air from the high-velocity discharge region of the fan, while the second region of the fin array faces and receives cooling air from the low-velocity discharge region of the fan. Further, in the fin array, cooling fins and/or portions of cooling fins disposed in the first region of the fin array have higher fluidic impedance than cooling fins and/or portions of cooling fins disposed in the second region of the fin array. Therefore, for a given velocity of cooling air flowing through the fin array, greater pressure drop is generated by the cooling fins and/or portions of cooling fins disposed in the first region relative to the pressure drop that is generated by the cooling fins and/or portions of cooling fins disposed in the second region. As a result, flow of air from the fan tends to flow toward the second (lower pressure drop) region of the fin array facing the hub region of the fan, thereby equalizing or making more uniform the velocity distribution of air flowing through the fin array.

### System Overview

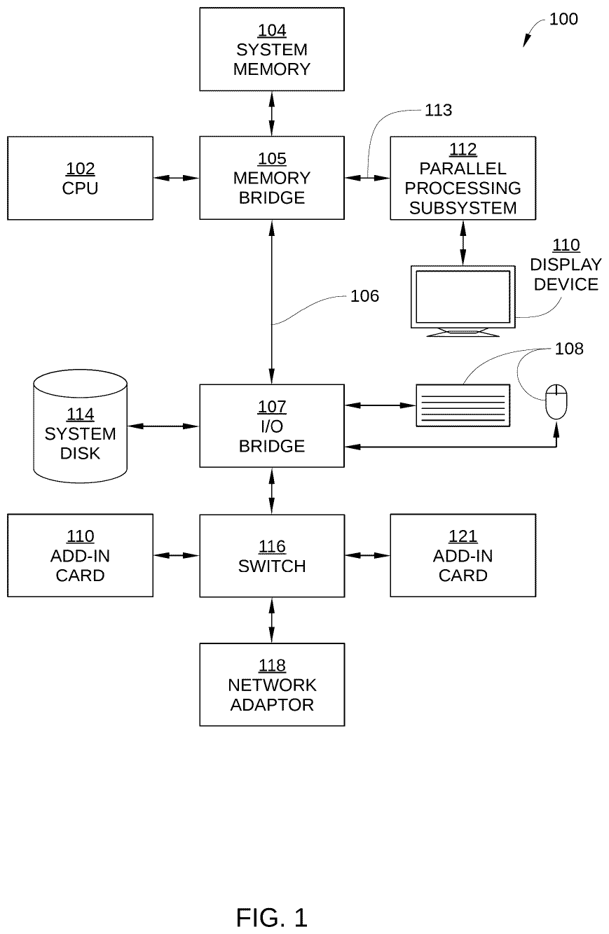

FIG. 1 is a conceptual illustration of a computer system 100 configured to implement one or more aspects of the various embodiments. As shown, system 100 includes a central processing unit (CPU) 102 and a system memory 104 communicating via a bus path that may include a memory bridge 105. CPU 102 includes one or more processing cores, and, in operation, CPU 102 is the master processor of system 100, controlling and coordinating operations of other system components. System memory 104 stores software applications and data for use by CPU 102. CPU 102 runs software applications and optionally an operating system. Memory bridge 105, which may be, e.g., a Northbridge chip, is connected via a bus or other communication path (e.g., a HyperTransport link) to an I/O (input/output) bridge 107. I/O bridge 107, which may be, e.g., a Southbridge chip, receives user input from one or more user input devices 108 (e.g., keyboard, mouse, joystick, digitizer tablets, touch pads, touch screens, still or video cameras, motion sensors, and/or microphones) and forwards the input to CPU 102 via memory bridge 105.

A display processor 112 is coupled to memory bridge 105 via a bus or other communication path (e.g., a PCI Express, Accelerated Graphics Port, or HyperTransport link); in one embodiment display processor 112 is a graphics subsystem that includes at least one graphics processing unit (GPU) and graphics memory. Graphics memory includes a display memory (e.g., a frame buffer) used for storing pixel data for each pixel of an output image. Graphics memory can be integrated in the same device as the GPU, connected as a separate device with the GPU, and/or implemented within system memory 104.

Display processor 112 periodically delivers pixels to a display device 110 (e.g., a screen or conventional CRT, plasma, OLED, SED or LCD based monitor or television). Additionally, display processor 112 may output pixels to film recorders adapted to reproduce computer generated images on photographic film. Display processor 112 can provide display device 110 with an analog or digital signal. In various embodiments, a graphical user interface is displayed to one or more users via display device 110, and the one or more users can input data into and receive visual output from the graphical user interface.

A system disk 114 is also connected to I/O bridge 107 and may be configured to store content and applications and data for use by CPU 102 and display processor 112. System disk 114 provides non-volatile storage for applications and data and may include fixed or removable hard disk drives, flash memory devices, and CD-ROM, DVD-ROM, Blu-ray, HD-DVD, or other magnetic, optical, or solid state storage devices.

A switch 116 provides connections between I/O bridge 107 and other components such as a network adapter 118 and various add-in cards 120 and 121. Network adapter 118 allows system 100 to communicate with other systems via an electronic communications network, and may include wired or wireless communication over local area networks and wide area networks such as the Internet.

Other components (not shown), including USB or other port connections, film recording devices, and the like, may also be connected to I/O bridge 107. For example, an audio processor may be used to generate analog or digital audio output from instructions and/or data provided by CPU 102, system memory 104, or system disk 114. Communication paths interconnecting the various components in FIG. 1 may be implemented using any suitable protocols, such as PCI (Peripheral Component Interconnect), PCI Express (PCI-E), AGP (Accelerated Graphics Port), HyperTransport, or any other bus or point-to-point communication protocol(s), and connections between different devices may use different protocols, as is known in the art.

In one embodiment, display processor 112 is configured as a processing subsystem that incorporates circuitry optimized for graphics and video processing, including, for example, video output circuitry, and constitutes a graphics processing unit (GPU). In another embodiment, display processor 112 is configured as a processing subsystem that incorporates circuitry optimized for general purpose processing. In yet another embodiment, display processor 112 may be integrated with one or more other system elements, such as the memory bridge 105, CPU 102, and I/O bridge 107 to form a system on chip (SoC). In still further embodiments, display processor 112 is omitted and software executed by CPU 102 performs the functions of display processor 112.

Pixel data can be provided to display processor 112 directly from CPU 102. In some embodiments, instructions and/or data representing a scene are provided to a render farm or a set of server computers, each similar to system 100, via network adapter 118 or system disk 114. The render farm generates one or more rendered images of the scene using the provided instructions and/or data. These rendered images may be stored on computer-readable media in a digital format and optionally returned to system 100 for display. Similarly, stereo image pairs processed by display processor 112 may be output to other systems for display, stored in system disk 114, or stored on computer-readable media in a digital format.

Alternatively, CPU 102 provides display processor 112 with data and/or instructions defining the desired output images, from which display processor 112 generates the pixel data of one or more output images, including characterizing and/or adjusting the offset between stereo image pairs. The data and/or instructions defining the desired output images can be stored in system memory 104 or graphics memory within display processor 112. In an embodiment, display processor 112 includes 3D rendering capabilities for generating pixel data for output images from instructions and data defining the geometry, lighting shading, texturing, motion, and/or camera parameters for a scene. Display processor 112 can further include one or more programmable execution units capable of executing shader programs, tone mapping programs, and the like.

Further, in other embodiments, CPU 102 or display processor 112 may be replaced with or supplemented by any technically feasible form of processing device configured process data and execute program code. Such a processing device could be, for example, a central processing unit (CPU), a graphics processing unit (GPU), an application-specific integrated circuit (ASIC), a field-programmable gate array (FPGA), and so forth. In various embodiments any of the operations and/or functions described herein can be performed by CPU 102, display processor 112, or one or more other processing devices or any combination of these different processors.

CPU 102, render farm, and/or display processor 112 can employ any surface or volume rendering technique known in the art to create one or more rendered images from the provided data and instructions, including rasterization, scanline rendering REYES or micropolygon rendering, ray casting, ray tracing, image-based rendering techniques, and/or combinations of these and any other rendering or image processing techniques known in the art.

In other contemplated embodiments, system 100 may or may not include other elements shown in FIG. 1. System memory 104 and/or other memory units or devices in system 100 may include instructions that, when executed, cause a robot or robotic device represented by system 100 to perform one or more operations, steps, tasks, or the like.

It will be appreciated that the system shown herein is illustrative and that variations and modifications are possible. The connection topology, including the number and arrangement of bridges, may be modified as desired. For instance, in some embodiments, system memory 104 is connected to CPU 102 directly rather than through a bridge, and other devices communicate with system memory 104 via memory bridge 105 and CPU 102. In other alternative topologies display processor 112 is connected to I/O bridge 107 or directly to CPU 102, rather than to memory bridge 105. In still other embodiments, I/O bridge 107 and memory bridge 105 might be integrated into a single chip. The particular components shown herein are optional; for instance, any number of add-in cards or peripheral devices might be supported. In some embodiments, switch 116 is eliminated, and network adapter 118 and add-in cards 120, 121 connect directly to I/O bridge 107.

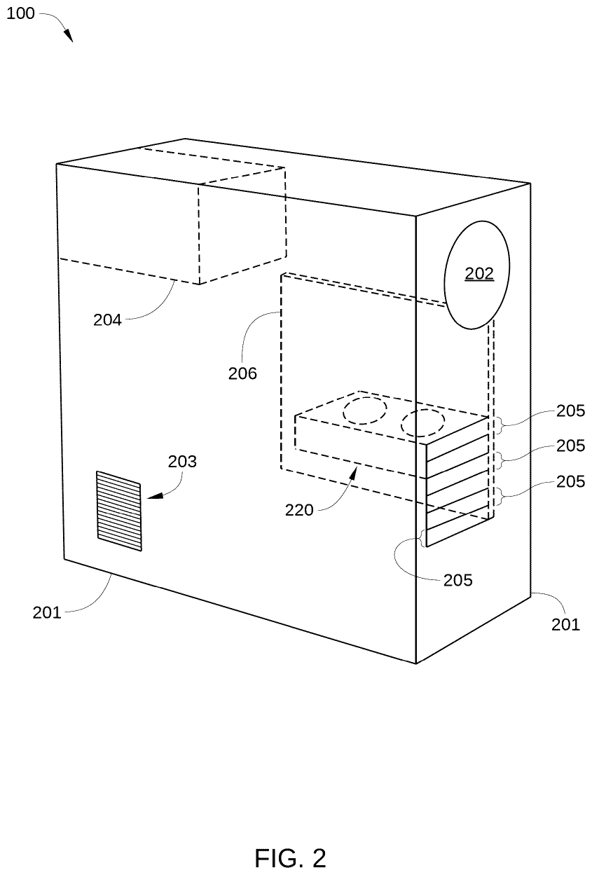

FIG. 2 is another illustration of computer system 100, according to various embodiments. As shown, computer system 100 includes a chassis 201 (also referred to as a “case” or “housing”) with one or more system cooling fans 202 mounted thereon and one or more cooling inlets 203 formed therein. Cooling fans 202 are configured to draw cooling air into chassis 201 to remove heat generated by various electronic components of computer system 100, for example via cooling inlets 203. In the embodiment illustrated in FIG. 2, computer system 100 further includes a power supply 204 mounted within chassis 201, a plurality of chassis expansion slots 205 that are typically located on a rear surface of chassis 201, and a motherboard 206 disposed within chassis 201.

Computer system 100 further includes various external connections (omitted for clarity) mounted on a rear and/or front surface of chassis 201, such as a power connection, Universal Serial Bus (USB) connections, an audio input jack, an audio output jack, one or more video output connections, and/or other connections. In some embodiments, one or more of such external connections are associated with motherboard 206 or an expansion card that is coupled to motherboard 206 and installed in a chassis expansion slot 205, such as a card-based processing subsystem 220.

In the embodiment illustrated in FIG. 2, motherboard 206 is configured with a central processing unit (CPU) and one or more card edge connectors, such as peripheral component interconnect express (PCIe) slots, that are each positioned to correspond to a different chassis expansion slot 205. For clarity, the CPU and card edge connectors of motherboard 206 are omitted in FIG. 2. Generally, computer system 100 is configured with one or more expansion cards or other card-based processing subsystems that are each mounted in a different chassis expansion slot 205 and communicatively coupled to motherboard 206 via a corresponding card edge connector. Examples of such card-based processing subsystems include card-based processing subsystems 220, such as wireless adapters, sound cards, graphics cards, network adapter 118, add-in cards 120, 121, or display processor 112 of FIG. 1, and/or the like. In the embodiment illustrated in FIG. 2, a single card-based processing subsystem 220 is coupled to motherboard 206, but in other embodiments, a plurality of card-based processing subsystems 220 may be coupled to motherboard 206.

In some embodiments, computer system 100 further includes one or more peripheral devices (not shown) that are communicatively coupled to motherboard 206 and/or a particular expansion card coupled to motherboard 206. For example, in some embodiments, computer system 100 includes one or more of a keyboard, mouse, joystick, digitizer tablet, touch pad, touch screen, display device, external hard drive, still or video cameras, motion sensors, microphones, and/or the like.

In the embodiment illustrated in FIG. 2, computer system 100 is depicted as a tower-configured desktop computer system. In other embodiments, computer system 100 can have any configuration that can include a card-based processing subsystem, such as a tower server computer system, a blade server computer system, a rack server computer system, a laptop computer, and/or the like.

### Card-based Processing Subsystem

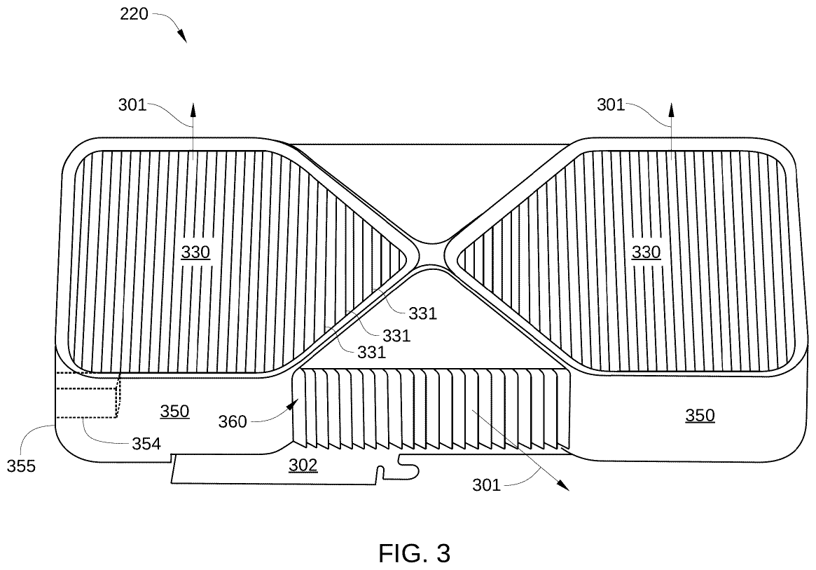

FIG. 3 is a more detailed illustration of card-based processing subsystem 220, according to various embodiments. Specifically, FIG. 3 is a perspective view of card-based processing subsystem 220, according to various embodiments. As shown, card-based processing subsystem 220 includes a housing 350 and one or more fin arrays 330 disposed within housing 350 for cooling one or more integrated circuits (ICs) included in card-based processing subsystem 220. In some embodiments, the one or more ICs are mounted on a printed circuit board (PCB) 302 that is disposed at least partially within housing 350.

In some embodiments, card-based processing subsystem 220 can be configured to occupy a region proximate motherboard 206 (shown in FIG. 2) that corresponds to one, two, three, or more chassis expansion slots 205. In such embodiments, backplate bracket 305 can have a suitable width (e.g., 20 mm, 40 mm, 60 mm, etc). Additionally or alternatively, in some embodiments, housing 350 has a form factor and electrical and mechanical connections (e.g., edge conductors, mechanical connection features, and backplate bracket) that enable the installation of card-based processing subsystem 220 onto a motherboard of a computer, such as motherboard 206 in FIG. 2. In such embodiments, housing 350 can have a form factor that occupies a region corresponding to an integral number of expansion slots on the motherboard.

In some embodiments, to increase heat removal from the ICs, a fan-based cooling system is included in card-based processing subsystem 220. In such embodiments, the fan-based cooling system includes one or more cooling fans (not visible in FIG. 3) that are oriented to force cooling air 301 (or any other suitable cooling fluid) through fin arrays 330. In the embodiment illustrated in FIG. 3, card-based processing subsystem 220 includes two cooling fans, where each cooling fan directs cooling air 301 through a different fin array 330 of card-based processing subsystem 220. In other embodiments, card-based processing subsystem 220 can include a single cooling fan or three or more cooling fans. In some embodiments, a portion of cooling air 301 can exit card-based processing subsystem 220 via one or more side vents 360 as shown.

In some embodiments, the fan-based cooling system of card-based processing subsystem 220 further includes a multi-phase thermal solution (not visible in FIG. 3), such as heat pipes and/or a vapor chamber. In such embodiments, the multi-phase thermal solution is thermally coupled to some or all of the ICs included in card-based processing subsystem 220, such as a GPU, a CPU, and/or a memory device or devices. In addition, the multi-phase thermal solution is coupled to some or all of the cooling fins 331 included in each fin array 330. In such embodiments, each fin array 330 acts as a heatsink for the fan-based cooling system of card-based processing subsystem 220. In some embodiments, housing 350 facilitates positioning of the cooling fans relative to PCB 302 disposed within housing 350, the multi-phase thermal solution, and fin arrays 330.

In some embodiments, housing 350 can include one or more connection ports 354 (shown in FIG. 3 as dashed lines) that are disposed on a front wall 355 of housing 350, such as a USB connection, an audio input jack, an audio output jack, one or more video output connections, and/or other connections. For example, in embodiments in which card-based processing subsystem 220 is configured as a graphics card, the one or more connection ports 354 can include a video connection, such as a video graphics array (VGA) connection, a digital video interface (DVI) connection, a high-definition multimedia interface (HDMI) connection, a DisplayPort, and/or the like. Generally, front wall 355 is a surface of card-based processing subsystem 220 that corresponds to a chassis expansion slot 205 of card-based processing subsystem 220 when card-based processing subsystem 220 is installed on motherboard 206 of computer system 100 (chassis expansion slots 205 and motherboard 206 are shown in FIG. 2).

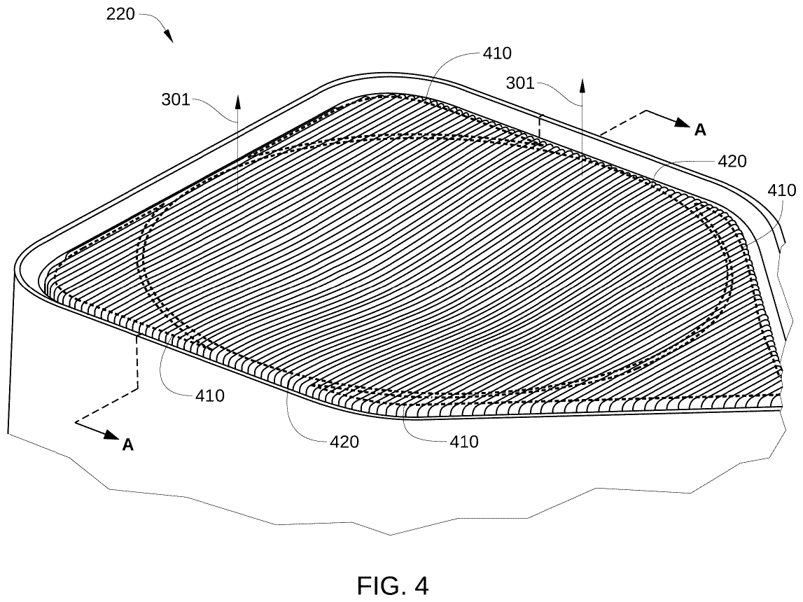

According to various embodiments, each fin array 330 is configured to increase the thermal performance of the fan-based cooling system of card-based processing subsystem 220 by more evenly distributing the flow of cooling air that is directed across cooling fins 331 of each fin array 330. One such embodiment is described below in conjunction with FIG. 4.

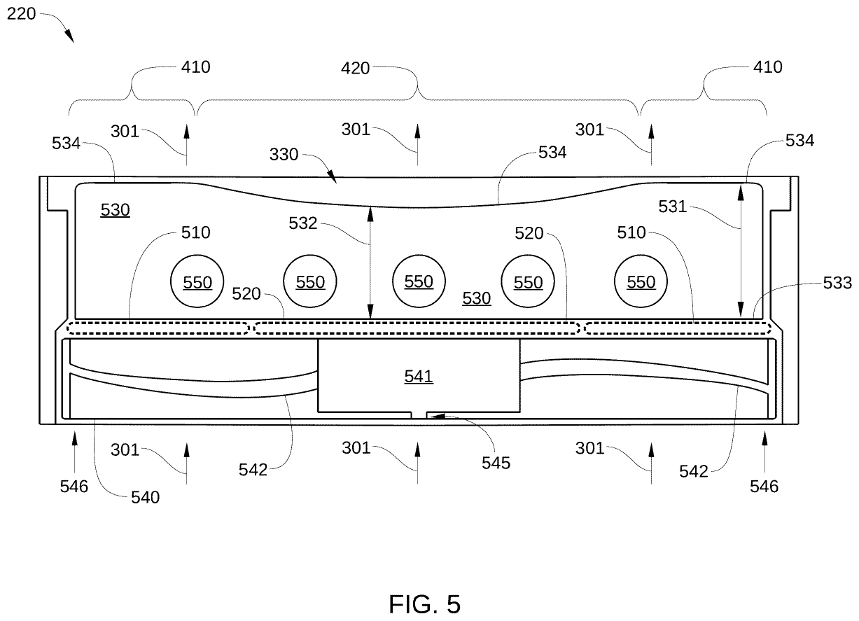

FIG. 4 is a closer perspective view of one portion of card-based processing subsystem 220, according to various embodiments. As shown, fin array 330 includes a plurality of cooling fins 331. In the embodiment illustrated in FIG. 4, cooling fins 331 can be thin, planar, metallic fins, such as stamped, machined, or extruded fins, and can be formed from aluminum, copper, or any other suitable fin material. As shown, cooling fins 331 are arranged in parallel with the flow of cooling air 301 that is discharged from an associated cooling fan (not visible in FIG. 4) and flows through fin array 330. Further, fin array 330 includes a first region 410 that corresponds to a high-velocity discharge region of the cooling fan (such as a perimeter region of the fan and a region proximate to the perimeter region of the fan) and a second region 420 that corresponds to a low-velocity discharge region of the fan (such as a hub region of the fan and a region proximate to the hub region of the fan). Thus, first region 410 faces and receives cooling air from the high-velocity discharge region of the fan, while second region 420 faces and receives cooling air from the low-velocity discharge region of the fan. In some embodiments, an outer portion of second region 420, for example the outer third of second region 420, can also face and receive cooling air from the high-velocity discharge region of the cooling fan, as shown in FIG. 5.

In the embodiment illustrated in FIG. 4, first region 410 includes multiple discontinuous subregions disposed around the perimeter of fin array 330. In other embodiments, first region 410 can be implemented as a single continuous region around the perimeter of fin array 330. By contrast, second region 420 is a single region disposed in a center portion of fin array 330 that corresponds to a hub region of the cooling fan.

According to various embodiments, in fin array 330, portions of cooling fins 331 that are disposed in first region 410 have higher fluidic impedance than portions of cooling fins 331 that are disposed in second region 420. Specifically, portions of cooling fins 331 in second region 420 have a smaller height than portions of cooling fins 331 disposed in first region 410. Therefore, for a given velocity of cooling air 301 flowing through fin array 330, greater pressure drop is generated by the portions of cooling fins 331 disposed in first region 410 relative to the pressure drop that is generated by portions of cooling fins 331 disposed in second region 420. In some embodiments, each cooling fin 331 that has a portion in second region 420 can have a different height profile. As a result, the exposed edges of the portions of cooling fins in second region 420 can form a three-dimensional region that has been “cut out” from the normally planar surface of a conventional fin array. For example, in the embodiment shown in FIG. 4, second region 420 forms a spherical “cut out” from fin array 330. The various heights of cooling fins 331 in first region 410 and second region 420 are described below in conjunction with FIG. 5.

### Non-uniform Heatsink Fin Geometry

FIG. 5 is a cross-sectional view of card-based processing subsystem 220, according to various embodiments. In FIG. 5, the cross-sectional view corresponds to a cross-sectional view taken at section A-A in FIG. 4. In the embodiment illustrated in FIG. 5, card-based processing subsystem 220 includes a cooling fan 540, a multi-phase thermal solution, and fin array 330. In section A-A, a single cooling fin 530 of fin array 330 is visible. Cooling fin 530 in FIG. 5 can be consistent with cooling fins 330 of FIGS. 3 and 4.

In the embodiment shown in FIG. 5, the multi-phase thermal solution includes a plurality of heat pipes 550 that are coupled to cooling fin 530 and to one or more ICs (not shown) of card-based processing subsystem 220. In other embodiments, the multi-phase thermal solution can include a vapor chamber coupled to cooling fin 530 and the one or more ICs. Heat pipes 550 employ evaporative cooling to transfer heat from the one or more IC to the cooling fins of fin array 330. As shown, the cooling fins of fin array 330 are oriented substantially parallel to the flow of cooling air 301 (or other cooling fluid) received from cooling fan 440 to facilitate the flow of cooling air 301 across the cooling fins.

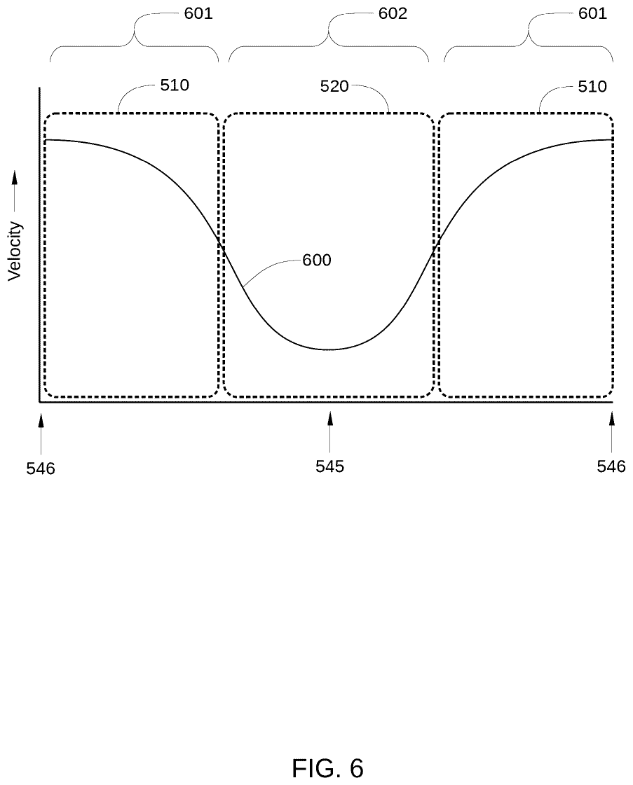

In the embodiment shown in FIG. 5, cooling fan 540 is an axial fan that includes a hub 541 and multiple fan blades 542. In operation, cooling fan 540 rotates about a shaft 545 coupled to hub 541 and directs cooling air 301 across cooling fin 530 and the other cooling fins of fin array 330. As noted above, cooling air 301 has a highly nonuniform velocity profile when discharged from cooling fan 540. Thus, in the embodiment illustrated in FIG. 5, cooling fan 540 has a high-velocity discharge region 510, which is proximate a perimeter 546 of cooling fan 540, and a low-velocity discharge region 520, which is proximate hub 541 of cooling fan 540. An example velocity profile of cooling fan 540 is described below in conjunction with FIG. 6.

FIG. 6 illustrates a discharge velocity profile 600 of cooling fan 540, according to various embodiments. Discharge velocity profile 600 conceptually depicts the velocity of cooling air 301 in FIG. 5 as a function of radial location relative to hub 545 and perimeter 546 of cooling fan 540 in FIG. 5. As shown, discharge velocity profile 600 includes high velocity values 601 for cooling air in high-velocity discharge region 510 and low velocity values 602 for cooling air in low-velocity discharge region 520. In many card-based processing subsystems, cooling fans that direct air across the cooling fins of a heatsink are positioned very close to the cooling fins. Therefore, the velocity distribution of cooling air being discharged by the cooling fan has little or no opportunity to equalize before flowing through the cooling fins of the heatsink and is similar to velocity profile 600. When cooling air flows through the cooling fins of a heatsink with such a nonuniform velocity profile, the portions of the cooling fins facing low-velocity discharge region 520 are underutilized and transfer significantly less heat to the cooling air than the portions of the cooling fins facing high-velocity discharge region 510.

According to various embodiments, cooling fins of a fan-based cooling system are configured to cause the velocity profile of cooling air when flowing across the cooling fins of a heatsink to be equalized or more uniform than the velocity profile of the cooling air when being discharged from a cooling fan. Various embodiments of cooling fins are described below in conjunction with FIGS. 5 and 8-10.

Returning to FIG. 5, cooling fin 530 has one or more portions that are disposed in first region 410 of fin array 330 and a portion that is disposed in second region 420 of fin array 330. As shown, the portion of cooling fin 530 disposed in first region 410 has a first fin height 531, while the portion of cooling fin 530 disposed in second region 420 has a second fin height 532 that is less than first height 531. In the embodiment illustrated in FIG. 5, each of first fin height 531 and second fin height 532 is measured between a leading edge 533 of cooling fin 530 and a trailing edge 534 of cooling fin 530.

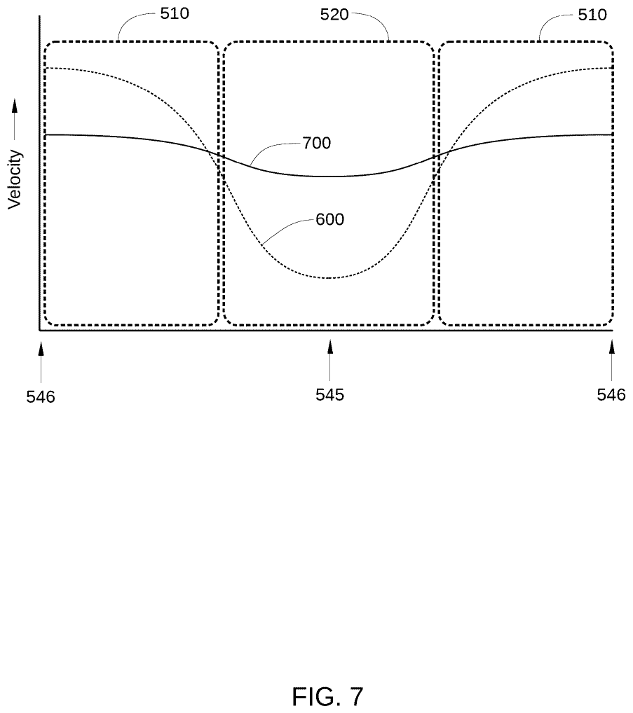

As shown, each of first fin height 531 and second fin height 532 is measured in a direction that is parallel with a direction of cooling air 301 flowing across fin array 330. Thus, first fin height 531 indicates a distance that cooling air 301 flows across cooling fin 530 in first region 410 and second fin height 532 indicates a distance that cooling air 301 flows across cooling fin 530 in second region 420. Because pressure drop generated by cooling fin 530 is proportional to the distance that cooling air 301 travels across cooling fin 530, the pressure drop generated by cooling fin 530 in second region 520 is less than the pressure drop generated by cooling fin 530 in first region 510. Consequently, more cooling air 301 flows through fin array 330 via second region 520 than when the portion of cooling fin 530 in second region 520 has the same fin height as the portion of cooling fin 530 in first region 510. As a result, cooling air 301 enters fin array 330 with an equalized or more uniform velocity profile than the velocity profile of cooling air 301 when discharged by cooling fan 540. An example velocity profile of cooling fan 540 is described below in conjunction with FIG. 7.

FIG. 7 illustrates a velocity profile 700 of cooling air entering fin array 330, according to various embodiments. Velocity profile 700 conceptually depicts the velocity of cooling air 301 entering fin array 330 as a function of radial location relative to hub 545 and perimeter 546 of cooling fan 540 (cooling air 301, fin array 330, and cooling fan 540 are shown in FIG. 5). For reference, discharge velocity profile 600 (dashed line) from FIG. 6 is also depicted in FIG. 7. As shown, velocity profile 700 is equalized and/or more uniform than discharge velocity profile 600. Thus, even though cooling fan 540 is disposed proximate fin array 300, velocity profile 700 is equalized and/or made more uniform than discharge velocity profile 600.

### Alternative Cooling Fin Geometries

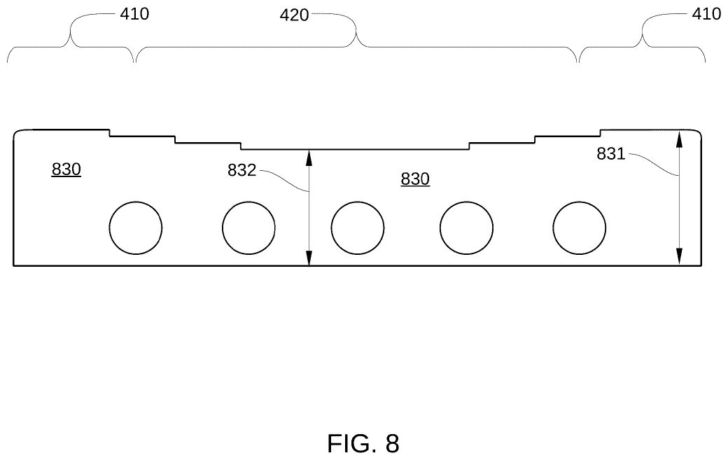

In the embodiments described above, a portion of a cooling fin in a cooling fin array has a curved trailing edge in a region of the cooling fin array that corresponds to a low-velocity discharge region of a cooling fan. In other embodiments, cooling fins with other geometries can be employed to equalize a cooling air velocity profile or make the cooling air velocity profile more uniform. Example embodiments are described below in conjunction with FIG. 8-10.

FIG. 8 illustrates a cooling fin 830 having stepwise changes in fin height, according to various embodiments. Cooling fin 830 can be a cooling fin included in a fin array of a card-based processing subsystem, such as card-based processing subsystem 220, and can be consistent with cooling fins 330 in FIGS. 3 and 4. As shown, cooling fin 830 has a first fin height 831 in first region 410 (which corresponds to a high-velocity discharge region of a cooling fan) and a second fin height 832 in second region 420 (which corresponds to a low-velocity discharge region of the cooling fan). In the embodiment illustrated in FIG. 8, second height 832 varies across second region 420, for example as a function of a discharge velocity profile of the cooling fan, such as discharge velocity profile 600 of FIG. 6. Further, second height 832 varies in a stepwise fashion between multiple different values that are each less than first fin height 831, rather than as a smooth curve. In some instances, cooling fin 830 can be more easily manufactured than a cooling fin with a curved trailing or leading edge.

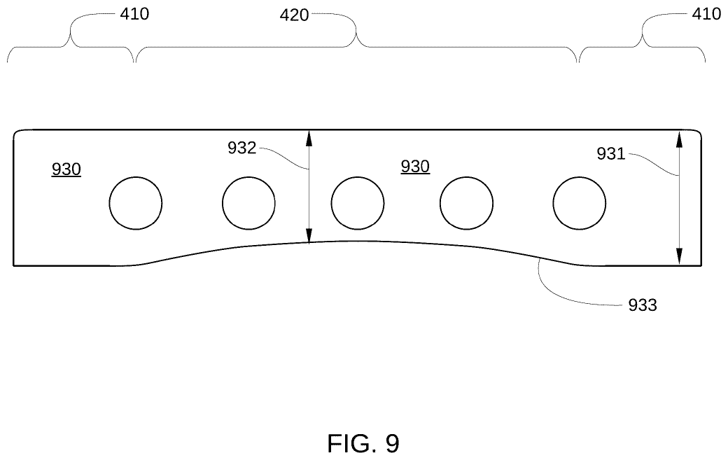

FIG. 9 illustrates a cooling fin 930 having a curved leading edge, according to various embodiments. Cooling fin 930 can be a cooling fin included in a fin array of a card-based processing subsystem, such as card-based processing subsystem 220, and can be consistent with cooling fins 330 in FIGS. 3 and 4. As shown, cooling fin 930 has a first fin height 931 in first region 410 and a second fin height 932 in second region 420. In the embodiment illustrated in FIG. 9, second height 932 varies across second region 420, for example as a function of a discharge velocity profile of the cooling fan, such as discharge velocity profile 600 of FIG. 6. Further, second height 932 varies due to a curved leading edge 933 of cooling fin 930 in second region 420.

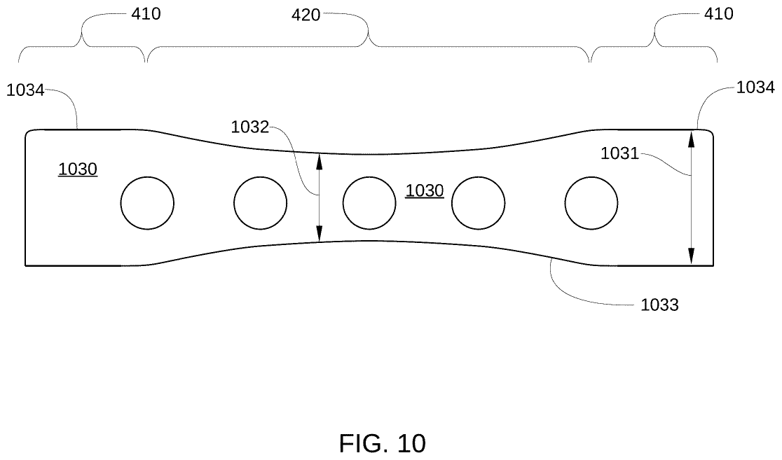

FIG. 10 illustrates a cooling fin 1030 having a both a curved leading edge and a curved trailing edge, according to various embodiments. Cooling fin 1030 can be a cooling fin included in a fin array of a card-based processing subsystem, such as card-based processing subsystem 220, and can be consistent with cooling fins 330 in FIGS. 3 and 4. As shown, cooling fin 1030 has a first fin height 1031 in first region 410 and a second fin height 1032 in second region 420. In the embodiment illustrated in FIG. 10, second height 1032 varies across second region 420, for example as a function of a discharge velocity profile of the cooling fan. Further, second height 1032 varies due to a curved leading edge 1033 and a curved trailing edge 1034 of cooling fin 1030.

In sum, the various embodiments shown and provided herein set forth techniques for improved cooling in card-based processing subsystems. Specifically, a fin array for a heatsink in a fan-based cooling system is configured to increase the thermal performance of the heatsink by more evenly distributing the flow of cooling air that is directed across the cooling fins of the heatsink by a fan. In the embodiments, the fin array includes a first region that corresponds to a high-velocity discharge region of the fan and a second region that corresponds to a low-velocity discharge region of the fan, where the first region of the fin array faces and receives cooling air from the high-velocity discharge region of the fan, and the second region of the fin array faces and receives cooling air from the low-velocity discharge region of the fan. Further, in the fin array, cooling fins and/or portions of cooling fins disposed in the first region of the fin array have higher fluidic impedance than cooling fins and/or portions of cooling fins disposed in the second region of the fin array. As a result, flow of air from the fan tends to flow toward the second (lower pressure drop) region of the fin array facing the hub region of the fan, thereby equalizing or making more uniform the velocity distribution of air flowing through the fin array.

At least one technical advantage of the disclosed design relative to the prior art is that the disclosed design can increase the thermal performance of a fan-based cooling system by more evenly distributing the flow of cooling air across the cooling fins of a heatsink. In particular, the disclosed design changes the fluidic impedance of the cooling fins of the heatsink locally, which reduces the pressure drop caused by the cooling fins in a region of the heatsink facing the fan hub relative to the pressure drop caused by the cooling fins in a region of the heatsink facing the fan perimeter. Consequently, the velocity distribution of air flowing through the cooling fins of a heatsink in accordance with the disclosed design is more equalized or more uniform relative to the velocity distribution of air flowing though the cooling fins of a conventional heatsink. As a result, thermal performance of the heatsink, and the fan-based cooling system as a whole, is increased. These technical advantages provide one or more technological advancements over prior art approaches.
1. In some embodiments, a heatsink includes: a plurality of cooling fins, wherein a first cooling fin included in the plurality of cooling fins has a first portion with a first height and has a second portion with a second height that is less than the first height, and wherein the first height and the second height are defined in a direction that is parallel with a direction of cooling air flowing across the plurality of cooling fins.
2. The heatsink of clause 1, wherein: the first portion of the first cooling fin is located proximate to a first discharge region of a fan; and the second portion of the first cooling fin is located proximate to a second discharge region of the fan.
3. The heatsink of clauses 1 or 2, wherein, in the first discharge region of the fan, cooling air with a first velocity is directed toward the plurality of fins, and, in the second discharge region of the fan, cooling air with a second velocity that is less than the first velocity is directed toward the plurality of fins.
4. The heatsink of any of clauses 1-3, wherein the first discharge region of the fan corresponds to a perimeter region of the fan, and the second discharge region of the fan corresponds to a hub region of the fan.
5. The heatsink of any of clauses 1-4, wherein: the first cooling fin includes a leading edge and a trailing edge; and both the first height and the second height are measured between the leading edge and the trailing edge of the first cooling fin.
6. The heatsink of any of clauses 1-5, wherein, across the second portion of the first cooling fin, the leading edge is straight, and the trailing edge is curved.
7. The heatsink of any of clauses 1-6, wherein, across the second portion of the first cooling fin, the leading edge is curved, and the trailing edge is straight.
8. The heatsink of any of clauses 1-7, wherein, across the second portion of the first cooling fin, the leading edge is curved, and the trailing edge is curved.
9. The heatsink of any of clauses 1-8, wherein, across the first portion of the first cooling fin, the leading edge is straight, and the trailing edge is straight.
10. The heatsink of any of clauses 1-9, wherein, across the second portion of the first cooling fin, the leading edge has one or more stepwise changes in fin height.
11. The heatsink of any of clauses 1-10, wherein, across the second portion of the first cooling fin, the trailing edge has one or more stepwise changes in fin height.
12. The heatsink of any of clauses 1-11, wherein a second cooling fin in the plurality of cooling fins has a third portion with a third fin height and a fourth portion with a fourth fin height that is less than the third fin height, and, wherein each of the third fin height and the fourth fin height is measured in a direction that is parallel with a direction of cooling air flowing across the plurality of cooling fins.
13. In some embodiments, a card-based processing subsystem includes: a housing; a processor mounted on a printed circuit board that is disposed within the housing; and a heatsink that is coupled to the processor, wherein the heatsink comprises: a plurality of cooling fins, wherein a first cooling fin included in the plurality of cooling fins has a first portion with a first height and a second portion with a second height that is less than the first height, and wherein each of the first height and the second height is measured in a direction that is parallel with a direction of cooling air flowing across the plurality of cooling fins.
14. The card-based processing subsystem of clause 13, further comprising a fan oriented to direct the cooling air across the plurality of cooling fins.
15. The card-based processing subsystem of clauses 13 or 14, wherein the fan is disposed within the housing.
16. The card-based processing subsystem of any of clauses 13-15, wherein: the first portion of the first cooling fin is located proximate to a first discharge region of the fan; and the second portion of the first cooling fin is located proximate to a second discharge region of the fan.
17. The card-based processing subsystem of any of clauses 13-16, wherein, in the first discharge region of the fan, cooling air with a first velocity is directed toward the plurality of fins, and, in the second discharge region of the fan, cooling air with a second velocity that is less than the first velocity is directed toward the plurality of fins.
18. The card-based processing subsystem of any of clauses 13-17, wherein the first discharge region of the fan corresponds to a perimeter region of the fan, and the second discharge region of the fan corresponds to a hub region of the fan.
19. The card-based processing subsystem of any of clauses 13-18, wherein: the first cooling fin includes a leading edge and a trailing edge; and both the first height and the second height are measured between the leading edge and the trailing edge of the first cooling fin.
20. The card-based processing subsystem of any of clauses 13-19, wherein a second cooling fin in the plurality of cooling fins has a third portion with a third fin height and a fourth portion with a fourth fin height that is less than the third fin height, and, wherein each of the third fin height and the fourth fin height is measured in a direction that is parallel with a direction of cooling air flowing across the plurality of cooling fins.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

While the preceding is directed to embodiments of the present disclosure, other and further embodiments of the disclosure may be devised without departing from the basic scope thereof, and the scope thereof is determined by the claims that follow.

What is claimed is:

1. A heatsink, comprising:
a plurality of cooling fins,
wherein a first cooling fin included in the plurality of cooling fins has a first portion with a first height and has a second portion with a second height that is less than the first height, and
wherein the first height and the second height are defined in a direction that is parallel with a direction of cooling air flowing across the plurality of cooling fins.

2. The heatsink of claim 1, wherein:
the first portion of the first cooling fin is located proximate to a first discharge region of a fan; and
the second portion of the first cooling fin is located proximate to a second discharge region of the fan.

3. The heatsink of claim 2, wherein, in the first discharge region of the fan, cooling air with a first velocity is directed toward the plurality of fins, and, in the second discharge region of the fan, cooling air with a second velocity that is less than the first velocity is directed toward the plurality of fins.

4. The heatsink of claim 2, wherein the first discharge region of the fan corresponds to a perimeter region of the fan, and the second discharge region of the fan corresponds to a hub region of the fan.

5. The heatsink of claim 1, wherein:
the first cooling fin includes a leading edge and a trailing edge; and
both the first height and the second height are measured between the leading edge and the trailing edge of the first cooling fin.

6. The heatsink of claim 5, wherein, across the second portion of the first cooling fin, the leading edge is straight, and the trailing edge is curved.

7. The heatsink of claim 5, wherein, across the second portion of the first cooling fin, the leading edge is curved, and the trailing edge is straight.

8. The heatsink of claim 5, wherein, across the second portion of the first cooling fin, the leading edge is curved, and the trailing edge is curved.

9. The heatsink of claim 8, wherein, across the first portion of the first cooling fin, the leading edge is straight, and the trailing edge is straight.

10. The heatsink of claim 5, wherein, across the second portion of the first cooling fin, the leading edge has one or more stepwise changes in fin height.

11. The heatsink of claim 5, wherein, across the second portion of the first cooling fin, the trailing edge has one or more stepwise changes in fin height.

12. The heatsink of claim 1, wherein a second cooling fin in the plurality of cooling fins has a third portion with a third fin height and a fourth portion with a fourth fin height that is less than the third fin height, and, wherein each of the third fin height and the fourth fin height is measured in a direction that is parallel with a direction of cooling air flowing across the plurality of cooling fins.

13. A card-based processing subsystem, comprising:
a housing;
a processor mounted on a printed circuit board that is disposed within the housing; and
a heatsink that is coupled to the processor, wherein the heatsink comprises:
a plurality of cooling fins,
wherein a first cooling fin included in the plurality of cooling fins has a first portion with a first height and a second portion with a second height that is less than the first height, and
wherein each of the first height and the second height is measured in a direction that is parallel with a direction of cooling air flowing across the plurality of cooling fins.

14. The card-based processing subsystem of claim 13, further comprising a fan oriented to direct the cooling air across the plurality of cooling fins.

15. The card-based processing subsystem of claim 14, wherein the fan is disposed within the housing.

16. The card-based processing subsystem of claim 14, wherein:
the first portion of the first cooling fin is located proximate to a first discharge region of the fan; and
the second portion of the first cooling fin is located proximate to a second discharge region of the fan.

17. The card-based processing subsystem of claim 16, wherein, in the first discharge region of the fan, cooling air with a first velocity is directed toward the plurality of fins, and, in the second discharge region of the fan, cooling air with a second velocity that is less than the first velocity is directed toward the plurality of fins.

18. The card-based processing subsystem of claim 16, wherein the first discharge region of the fan corresponds to a perimeter region of the fan, and the second discharge region of the fan corresponds to a hub region of the fan.

19. The card-based processing subsystem of claim 13, wherein:
the first cooling fin includes a leading edge and a trailing edge; and
both the first height and the second height are measured between the leading edge and the trailing edge of the first cooling fin.

20. The card-based processing subsystem of claim 13, wherein a second cooling fin in the plurality of cooling fins has a third portion with a third fin height and a fourth portion with a fourth fin height that is less than the third fin height, and, wherein each of the third fin height and the fourth fin height is measured in a direction that is parallel with a direction of cooling air flowing across the plurality of cooling fins.
